(19) United States
(12) Patent Application Publication
(10) Pub. No.: US 2009/0188553 A1
(43) Pub. Date: Jul. 30, 2009

(54) Methods of fabricating solar-cell structures and resulting solar-cell structures

(75) Inventor: Valery M. Dubin, Portland, OR (US)

Correspondence Address: GRAYBEAL JACKSON LLP, 155 - 108TH AVENUE NE, SUITE 350, BELLEVUE, WA, 98004-5973, US

(73) Assignee: eMat Technology, LLC, Moses Lake, WA (US)

(21) Appl. No.: 12/011,259

(22) Filed: Jan. 25, 2008

(51) Int. Cl. H01L 31/20; C25D 5/50

(52) U.S. Cl. 136/256; 205/112

(57) ABSTRACT

Embodiments of the invention relate to methods of fabricating solar-cell structures and resulting solar-cell structures. In one embodiment of a method of fabricating a solar-cell structure, a substrate including a front surface and an opposing back surface is provided. A porous-silicon layer may be electrochemically formed from a portion of the substrate that extends inwardly from the front surface. A portion of the porous-silicon layer may be electrochemically passivated. Metallic material may be plated to form at least a portion of each of a plurality of electrical contacts that are in electrical contact with the substrate. In a method according to another embodiment of the invention, the porous-silicon layer may used to getter impurities present in the substrate. In such an embodiment, the porous-silicon layer may be removed after gettering.

### BACKGROUND

A solar cell is a device that converts solar radiation into electrical energy. A solar cell includes a light-absorbing structure (e.g., a diode formed in a semiconductor material) capable of generating charge carriers (i.e., electrons and holes) responsive to absorbing solar radiation. The solar cell also includes electrical contacts that transmit the photo-generated charge carriers as current for powering an external circuit.

Solar cells have many applications and have long been used in situations where electrical power from the grid is unavailable, such as in remote-area power systems, satellites and space probes, consumer systems (e.g. handheld calculators or wrist watches), remote radiotelephones, and water pumping applications.

The importance of solar cells has increased with the ever increasing concern for global warming and generation of greenhouse gases. The use of solar cells is a possible solution for reducing greenhouse gas emissions. However, in order for solar cells to be adopted for widespread use, the cost of solar cells needs to become cost-competitive with other sources of energy, such as oil and natural gas.

### SUMMARY

Embodiments of the invention relate to methods of fabricating solar-cell structures and resulting solar-cell structures. In a method of fabricating a solar-cell structure according to one embodiment of the invention, a substrate including a front surface and an opposing back surface is provided. A porous-silicon layer may be electrochemically formed from a portion of the substrate that extends inwardly from the front surface. A portion of the porous-silicon layer may be electrochemically passivated. Metallic material may be plated to form at least a portion of each of a plurality of electrical contacts that are electrically coupled to the substrate.

In a method according to another embodiment of the invention, the porous-silicon layer may used to getter impurities present in the substrate. In such an embodiment, the porous-silicon layer may be removed after gettering.

In another embodiment of the invention, a solar-cell structure is disclosed. The solar-cell structure includes a substrate having a front surface and an opposing back surface. The substrate includes a semiconductor structure having at least one p-region and at least one n-region, a porous-silicon layer formed in a portion of the substrate, and a passivation layer formed from a portion of the porous-silicon layer and extending inwardly from the front surface. The solar-cell structure further includes a plurality of electrical contacts electrically coupled to the semiconductor structure, wherein at least a portion of each of the electrical contacts including a plated portion.

### BRIEF DESCRIPTION OF THE DRAWINGS

The drawings illustrate several embodiments of the invention, wherein like reference numerals refer to like components or features in different views or embodiments shown in the drawings.

FIGS. 1A-1I and 1K are cross-sectional views illustrating various stages in a method of fabricating a solar-cell structure having a plurality of plated, buried electrical contacts according to various embodiments of the invention.

FIG. 1J is a plan view of the in-process structure shown in FIG. 1I.

FIGS. 2A-2D are cross-sectional views illustrating various stages in a method of fabricating a solar-cell structure having a plurality of plated, buried electrical contacts according to another embodiment of the invention.

FIGS. 3A-3F are cross-sectional views illustrating various stages in a method of fabricating a solar-cell structure having a plurality of rear-plated electrical contacts formed according to another embodiment of the invention.

FIG. 3G is a plan view after forming a dielectric layer and bus bars over the passivation and metallization layers disposed on the back surface shown in FIG. 3F.

FIGS. 4A-4G are cross-sectional views illustrating various stages in a method of fabricating a solar-cell structure by selectively plating electrical contacts onto electrical contact regions formed in a photo-catalytic layer according to another embodiment of the invention.

FIGS. 5A-5D are cross-sectional views illustrating various stages in a method of fabricating a solar-cell structure having a plurality of electrical contacts including a screen-printed portion and a plated portion according to another embodiment of the invention.

### DETAILED DESCRIPTION

Embodiments of the invention relate to methods of fabricating solar-cell structures using electrochemical processing and resulting solar-cell structures. For example, a solar-cell structure may be formed by electrochemically forming a porous-silicon layer from a portion of a silicon substrate, electrochemically passivating a portion of the porous-silicon layer, and plating (e.g., by electroplating or electroless plating) metallic material to form at least a portion of each of a plurality of electrical contacts that are electrically coupled to the silicon substrate (e.g., electrically coupled to a diode formed in the silicon substrate).

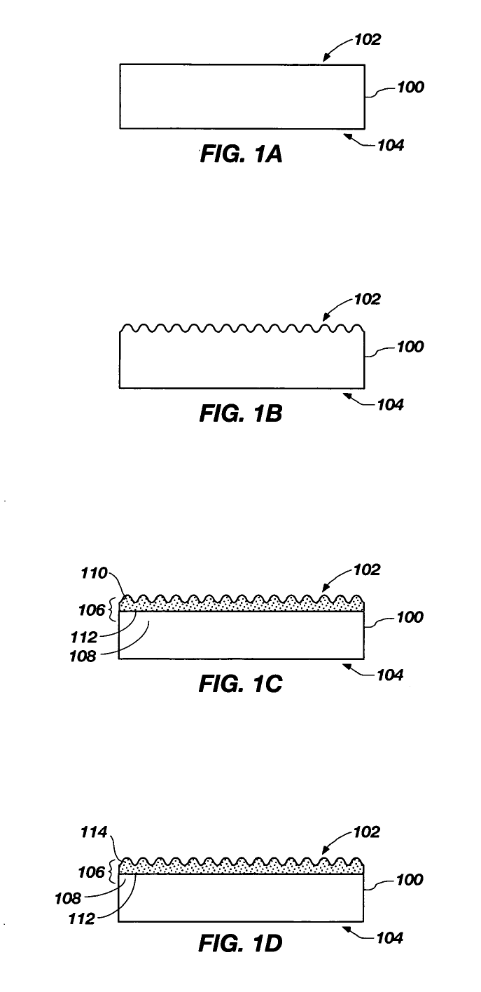

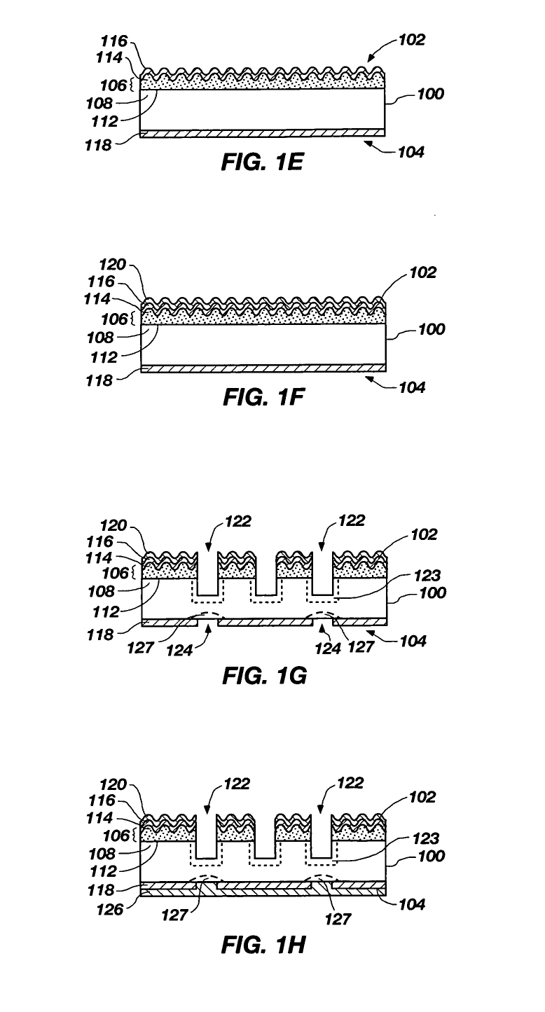

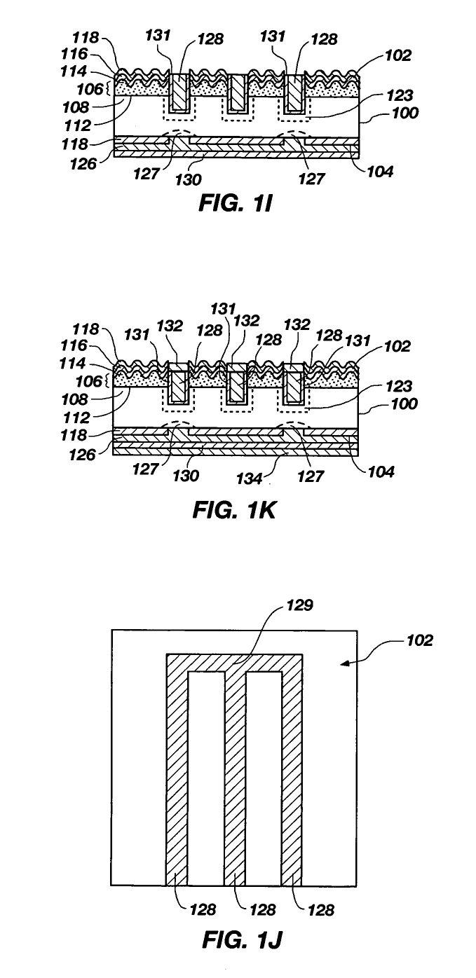

FIGS. 1A-1K are different views illustrating various stages in a method of fabricating a solar-cell structure having a plurality of plated, buried electrical contacts according to various embodiments of the invention. Referring to FIG. 1A, a silicon substrate 100 of a first type of conductivity and having a front surface 102 and an opposing back surface 104 is provided. The silicon substrate 100 may be a single-crystalline silicon substrate or a polycrystalline silicon substrate, each of which may be of a lower quality than typically used for integrated circuits.

Referring to FIG. 1B, the front surface 102 of the silicon substrate 100 may be textured to provide a substantially non-reflective surface to the dominant wavelengths in the solar radiation spectrum. Although in the illustrated embodiment, only the front surface 102 is textured, in other embodiments, both the front surface 102 and the back surface 104 may be textured. For example, the front surface 102 may be anisotropically etched using a potassium hydroxide-based or tetramethyl ammonium hydroxide (“TMAH”)-based alkaline etchant at a temperature of about 80° C. or more. In another embodiment, the front surface 102 may be anisotropically etched using hydrofluoric/nitric acid-based etchant. Utilizing either of the above-described etchants may result in forming pyramidal structures on the front surface 102 of the silicon substrate 100 due to preferentially etching specific crystal planes of the silicon substrate 100. However, in some embodiments of the invention, the front surface 102 may not be chemically textured.

Referring to FIG. 1C, the silicon substrate 100 may be doped to form a p-n semiconductor structure 106 (i.e., a diode) having a p-region 108, an n-region 110, and a p-n junction 112 therebetween buried below and proximate to the front surface 102. For example, when the silicon substrate 100 is made from p-type silicon, the silicon substrate 100 may be doped with phosphorous from a mixture of POCl₃ and oxygen vapor at a temperature of 700° C. to form the n-region 110, with the bulk of the silicon substrate 100 serving as the p-region 108. Any phosphorous-containing glass remaining on the front surface 102 may be removed using a suitable etchant, such as a hydrofluoric acid-based etchant.

Referring to FIG. 1D, a porous-silicon layer 114 may be electrochemically formed by anodically etching the n-region 110 of the silicon substrate 100. For example, the front surface 102 of the silicon substrate 100 may be contacted with and anodically etched in a 10 percent to 40 percent hydrofluoric acid solution at an anode current density of about 1 mA/cm² to about 100 mA/cm²to form the porous-silicon layer 114 from substantially all or only a portion of the n-region 110. The porous-silicon layer 114 exhibits an energy band gap that is greater than an energy band gap of the non-porous silicon that forms the bulk of the silicon substrate 100, which helps prevent photo-generated carriers from recombining at the front surface 102.

It is noted that the order of the texturing, doping, and anodic etching acts may occur in any order. For example, the front surface 102 may be textured, followed by forming the porous-silicon layer 114. The doping may be performed after forming the porous-silicon layer 114. Additionally, the front surface 112 may be textured after forming the porous-silicon layer 114 and doping.

Referring to FIG. 1E, the porous-silicon layer 114 may be electrochemically passivated to form a passivation layer 116 by exposing the porous-silicon layer 114 to a suitable acidic or basic solution under anodic conditions. For example, the passivation layer 116 may be formed by exposing the porous-silicon layer 114 to formic acid, orthophosphoric acid, dilute aqueous ammonium hydroxide (“NH₄OH”), or TMAH under anodic conditions to oxidize at least a portion of the porous-silicon layer 114. The passivation layer 114 may comprise a dense silicon dioxide layer that has a chemistry characteristic of being electrochemically formed, such as hydroxyl groups bonded to surfaces thereof. As illustrated, in some embodiments of the invention, the back surface 104 of the silicon substrate 100 may also be electrochemically passivated at the same time as the porous-silicon layer 114 to form a passivation layer 118 (e.g., silicon dioxide). The passivation layers 116 and 118 may also help reduce photo-generated carriers from recombining at the front surface 102 and the back surface 104.

Referring to FIG. 1F, in some embodiments, an anti-reflection coating (“ARC”) 120 may be deposited on the passivation layer 116 to further enhance the non-reflecting properties of the textured front surface 102. For example, the ARC 120 may comprise silicon nitride (“Si₃N₄”) or titanium dioxide (“TiO₂”) deposited on the passivation layer 116 via a low-temperature chemical vapor deposition (“CVD”) process or a spin-on deposition process. However, in some embodiments of the invention, the ARC 120 may be omitted.

Referring to FIG. 1G, a plurality of grooves 122 may be formed in the silicon substrate 100 that extend from at least the front surface 102 to an intermediate depth within the silicon substrate 100. Each groove 122 may be formed by laser ablation of the in-process structure shown in FIG. 1F, photolithographically patterning and etching the in-process structure shown in FIG. 1F, or another suitable technique. Each groove 122 may have a width of about 0.1 μm to about 50 μm, and more particularly about 0.1 μm to about 1 μm. Each groove 122 extends partially or completely through a thickness of the substrate 100. When the passivation layer 118 is present, openings 124 (e.g., grooves) may also be formed through the passivation layer 118 to expose the underlying silicon substrate 100 by photolithographically patterning and etching through the passivation layer 118 or another suitable material-removal process. After forming the grooves 122, a doped region 123 may be formed adjacent to each groove 122 using the same doping techniques described with respect to FIG. 1C. Additionally, after forming the openings 124, a doped region 127 may be formed adjacent to each opening 124 using the same doping techniques described with respect to FIG. 1C. Such doped regions 123 and 127 help reduce contact resistance with electrical contacts that, are ultimately, formed in the grooves 122 and the openings 124.

Referring to FIG. 1H, a metallization layer 126 may be deposited over the passivation layer 118 of the back surface 104 of the silicon substrate 100. For example, the metallization layer 126 may be formed over passivation layer 118 to fill the openings 124 (FIG. 1G) formed therein using electroless plating, electroplating, chemical vapor deposition (“CVD”), atomic layer deposition (“ALD”), sputtering, or evaporation of a selected metal or alloy. The metallization layer 126 is in electrical contact with the silicon substrate 100. In one embodiment of the invention, the metallization layer 126 may be made from an aluminum-copper alloy that may be deposited via electroless or electroplating, ALD, CVD, sputtering, or evaporation over the passivation layer 118.

Referring to FIG. 1I, a plurality of electrically interconnected, buried electrical contacts 128 may be formed by plating metallic material into each groove 122 (FIG. 1H). Because the width of each groove 124 may be less than 1 μm, incident solar radiation may not be significantly obstructed by the buried electrical contacts 128. In one embodiment of the invention, each buried electrical contact 128 is formed by electroplating metallic material into each groove 122. In another embodiment of the invention, each buried electrical contact 128 is formed by electrolessly plating the metallic material into each groove 122. For example, the metallic material that forms each buried electrical contact 128 may be selected from copper, nickel, gold, silver, palladium, and alloys of any of the preceding metals. The electroless plating solution and the electroplating solution may be formulated so that substantially none or insignificant amounts of the metallic material is plated on portions of the in-process structure outside of the grooves 122. Additionally, the plating solution may be formulated with specific additives that promote filling each groove 122 from the bottom to prevent forming voids or other defects in the buried electrical contacts 128. For example, when plating copper, one embodiment of an electroplating solution is a copper electrolyte including about 10 to about 100 grams per litter (“g/L”) copper, about 5 to about 250 g/L sulfuric acid, about 10 to about 100 mg/L hydrochloric acid, about 5 to about 500 mg/l of organic additives, such as accelerators, levelers, suppressors, or combinations thereof.

In some embodiments of the invention, the metallic material may include one or more barrier-forming constituents, such as one or more refractory metals (e.g., tungsten, molybdenum, rhenium, or zirconium). For example, a silver-tungsten alloy or a copper-tungsten alloy may be plated to form the buried electrical contacts 128, followed by annealing at a temperature below about 400° C. to cause the tungsten to segregate to the respective interfaces between the as-plated metallic material and the silicon substrate 100 and form respective barrier layers that each comprises predominately refractory metal.

Still referring to FIG. 1I, in one embodiment of the invention, when the metallization layer 126 is formed from an aluminum-copper alloy, a nickel layer 131 (i.e., a barrier/adhesion layer) may be electrolessly plated to partially fill each groove 122 prior to plating the buried electrical contacts 128 thereon and a nickel-containing layer 130 may also be substantially simultaneously plated onto the metallization layer 126. The copper present in the aluminum-copper alloy of the metallization layer 126 may function as a catalyst to promote electroless deposition of nickel onto the metallization layer 126 without having to pre-treat the metallization layer 126. In some embodiments of the invention, the structure shown in FIG. 1I may be annealed at, for example, a temperature between about 300° C. to about 400° C. so that the as-plated nickel layer 131 of the buried electrical contacts 128 reacts with silicon from the silicon substrate 100 to form a low-contact-resistance nickel-silicide layer at an interface with the silicon substrate 100. In one embodiment of the invention, each buried electrical contact 128 comprises electrolessly plated or electroplated copper or silver that is plated onto a corresponding nickel layer 131 to substantially fill a corresponding groove 122 and, further, may also be plated onto the nickel-containing layer 130.

Referring to FIG. 1J, each buried electrical contact 128 may be electrically interconnected via a buried bus bar 129 that is also formed in a groove (not shown) formed in the silicon substrate 100 in the same process as the grooves 122. The buried bus bar 129 may be formed in the same plating process as the buried electrical contacts 128 and, thus, may be fabricated from the same type of plated materials and integrally formed with the buried electrical contacts 128. It should be noted, that although only three buried electrical contacts 128 are illustrated, significantly more than three buried electrical contacts 128 may be formed and electrically interconnected to the bus bar 129.

Referring to FIG. 1K, if desired to improve solderability, in some embodiments of the invention, a solder-wettable layer 132 may be plated onto respective upper surfaces of each buried electrical contact 128 and the buried bus bar 129, and a solder-wettable layer 134 may also be plated onto the nickel-containing layer 130 or, if present, the copper or silver plated onto the nickel-containing layer 130. The solder-wettable layers 132 and 134 may each comprise copper, tin, a noble metal (e.g., gold, silver, or palladium), or alloys of any of the preceding metals that is electrolessly plated, electroplated, or plated via contact displacement deposition. Forming the solder-wettable layers 132 and 134 with one or more noble metals may improve the corrosion resistance thereof. The solder-wettable layers 132 and 134 may be wettable by a number of conventional solder alloys, such as tin- or lead-based solders so that external electrical connections may be connected to the buried bus bar 129 and the metallization layer 126.

During use, the front surface 102 of the solar-cell structure shown in FIG. 1K is irradiated with solar radiation that generates electron-hole pairs proximate to the front surface 102 that are collected by the buried electrical contacts 128 and the metallization layer 126 to provide current that may power an external circuit.

In another embodiment of the invention, the porous-silicon layer 114 may be employed to getter at least a portion of impurities that are present in the silicon substrate 100. Impurities in the silicon substrate 100 m ay be gettered in the porous-silicon layer 114 by annealing the silicon substrate 100 at a sufficient temperature and for a sufficient time to allow diffusion of the impurities therein into the porous-silicon layer 114. Thus, the porous-silicon layer 114 allows a relatively low-cost, low-grade silicon substrate to be employed because impurities present therein may be gettered in the porous-silicon layer.

When the porous-silicon layer 114 is used for gettering impurities, it should be removed after gettering by etching, such as in a TMAH solution or other etchant, followed by passivation to form a silicon dioxide layer, as previously described. For example, the porous-silicon layer 114 may be formed in only an upper portion of the n-region 110 shown in FIG. 1C, on the back surface 104, or both and removed after gettering so that an in-process structure having a structure similar to the structure in FIG. 1C remains. Then, the passivation layer 116 may be formed from the remaining n-region 110 and the passivation layer 118 may be formed, followed by deposition of the optional ARC 120, formation of the grooves 122, and the electrical contacts 128 and back side metallization layers. In other embodiments of the invention, the buried p-n junction 112 may be formed by doping after gettering in a porous-silicon layer and removal thereof.

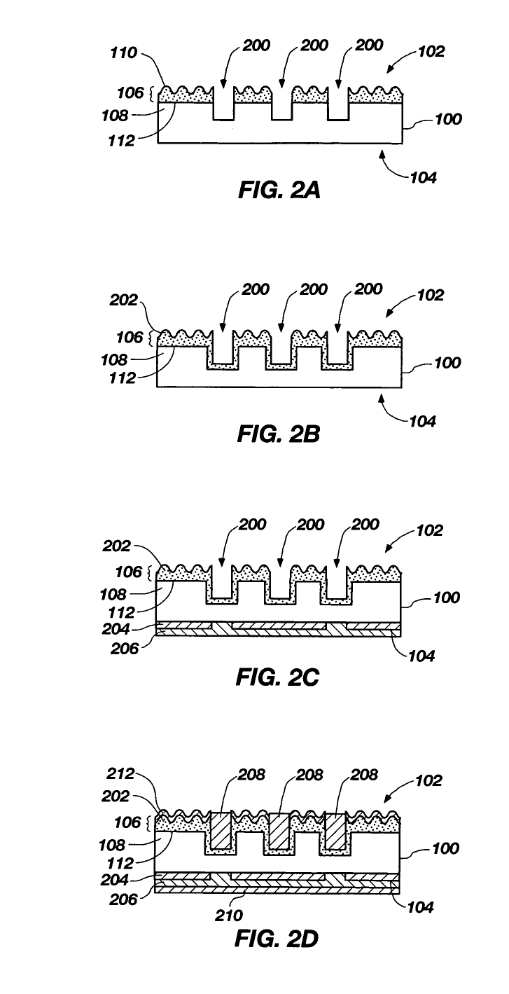

FIGS. 2A-2D are different views illustrating various stages in a method of fabricating a solar-cell structure having a plurality of plated, buried electrical contacts according to another embodiment of the invention. The method described with respect to FIGS. 2A-2D mainly differs from the embodiments described with respect to FIGS. 1A-1K in that buried electrical contacts are plated onto an adhesion-promoting porous-silicon layer that defines each groove formed in the silicon substrate 100. Referring to FIG. 2A, a plurality of grooves 200 are formed in the silicon substrate 100 of the in-process structure shown in FIG. IC using laser ablation, etching, or another suitable technique. Although not shown, a bus-bar groove may also be formed similar to that described with respect to the embodiments shown in FIGS. 1A-1K.

Referring to FIG. 2B, a porous-silicon layer 202 may be electrochemically formed using the same process techniques previously described for forming the porous-silicon layer 114 shown in FIG. 1D. The porous-silicon layer 202 defines each groove 200 (including the bus-bar groove) to provide an adhesion-promoting surface for plating various metallic materials thereon. Additionally, the porous-silicon layer 202 may help prevent photo-generated carriers from recombining at the front surface 102, as previously described. Although not shown in FIG. 2B, the porous-silicon layer 202 may also be formed on the back surface 104 of the silicon substrate 100.

Referring to FIG. 2C, the back surface 104 of the silicon substrate 100 may be electrochemically passivated to form a passivation layer 204 using the same passivation techniques described with respect to the passivation layer 116 shown in FIG. 1E. Grooves or other openings in the passivation layer 204 may be formed (e.g., by etching) and a metallization layer 206 may be deposited over the passivation layer 204 to fill the grooves and electrically contact the silicon substrate 100. For example, the metallization layer 206 may comprise an aluminum-copper alloy that is sputtered, deposited via CVD, deposited via ALD, or evaporated over the passivation layer 204.

Referring to FIG. 2D, metallic material may be plated onto the porous-silicon layer 202 defining each groove 200 to form a plurality of buried electrical contacts 208 and onto the porous-silicon layer 202 defining the bus-bar groove (not shown) to form a bus bar (not shown) that electrically interconnects each buried electrical contact 208. The buried electrical contacts 208 and bus bar may be plated using any of the previously described plating processes and materials (e.g., electroless plating or electroplating). The porous-silicon layer 202 may promote adhesion of the plated metallic material that forms the buried electrical contacts 208. Although not shown, respective doped regions may be formed adjacent to the grooves 200 and openings in the passivation layer 204 prior to forming the buried electrical contacts 208 and the metallization layer 206 to help reduce contact resistance therewith.

In the illustrated embodiment, when the metallization layer 206 comprises an aluminum-copper alloy, the buried electrical contacts 208 may comprise electrolessly plated nickel or a nickel alloy. In such an embodiment, a nickel-containing layer 210 may also be electrolessly plated on the metallization layer 206 at substantially the same time as the buried electrical contacts 208 and bus bar are plated. Additionally, after deposition of the buried electrical contacts 208, bus bar, and nickel-containing layer 210, a solder-wettable layer (e.g., a layer comprising copper, tin, a noble metal, or alloys thereof) may be plated on respective upper surfaces of the buried electrical contacts 208, bus bar, and the nickel-containing layer 210 to improve solderability using any of the aforementioned plating techniques.

Still referring to FIG. 2D, an exposed portion of the porous-silicon layer 202 may be electrochemically passivated to form a passivation layer 212 using the same passivation techniques described with respect to the passivation layer 116 shown in FIG. 1E. Although not shown, in some embodiments, an ARC may be formed over the passivation layer 212.

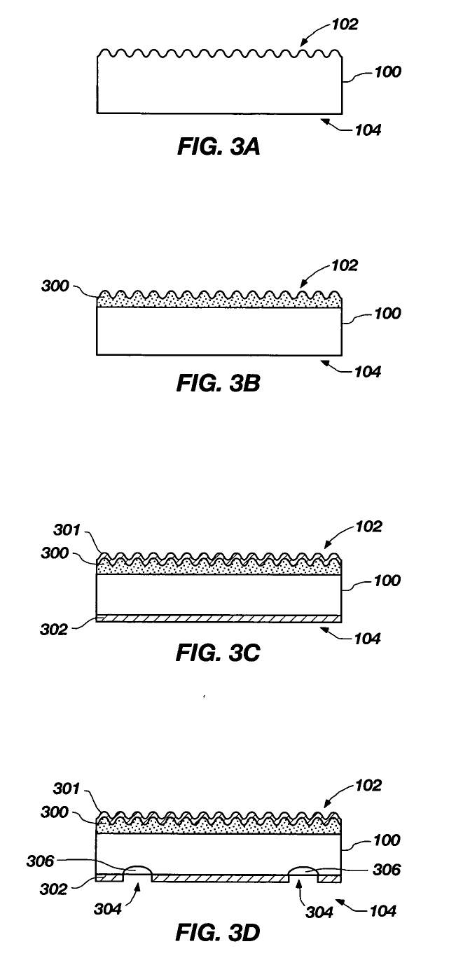

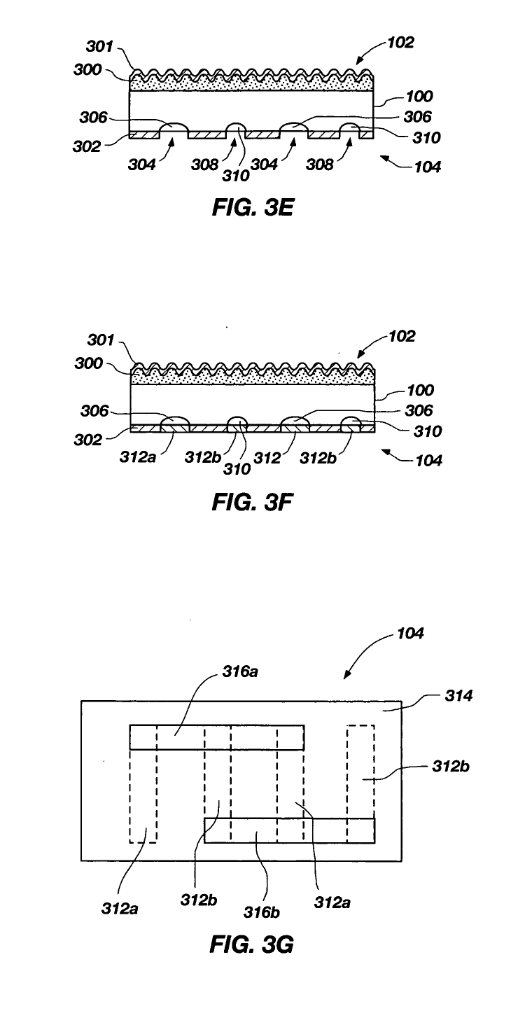

FIGS. 3A-3G are different views illustrating various stages in a method of fabricating a solar-cell structure having a plurality of rear-plated electrical contacts formed according to another embodiment of the invention. Referring to FIG. 3A, the in-process structure shown in FIG. 1B including the silicon substrate 100 having the front surface 102 thereof textured (e.g., via etching) is provided. However, as with the previously described embodiments, the front surface 102 may not be textured in some embodiments. Furthermore, in some embodiments of the invention, an ARC (not shown) may be deposited to conformally coat the front surface 102.

Referring to FIG. 3B, a porous-silicon layer 300 may be electrochemically formed using an anodic etching process as previously discussed with respect to forming the porous-silicon layer 114 shown in FIG. 1D.

Referring to FIG. 3C, a portion of the porous-silicon layer 300 may be electrochemically passivated to form a passivation layer 301 and the back surface 104 of the substrate 100 may also be electrochemically passivated to form a passivation layer 302. The passivation layer 302 may be formed using the same electrochemical passivation techniques previously described with respect to the passivation layer 116 shown in FIG. 1E. It is noted that in another embodiment of the invention, the in-process structure shown in FIG. 3B may be annealed to getter impurities of the silicon substrate 100 into the porous-silicon layer 300 followed by removing the porous-silicon layer 300 by etching, and passivation of the remaining etched surface of the silicon substrate 100 using any of the aforementioned electrochemical passivation techniques.

Referring to FIG. 3D, a plurality of openings 304 (e.g., grooves) may be formed through the passivation layer 302 to expose the underlying silicon substrate 100. For example, each opening 304 may be formed by photolithographically patterning and etching the passivation layer 302 or another suitable technique. The underlying silicon-substrate 100 may be selectively doped adjacent to each opening 304 to form a respective doped region 306. For example, the doped regions 306 may be n-type doped by depositing a phosphorous glass over the passivation layer 302 and in each opening 304 and annealing to diffuse the phosphorous into the silicon substrate 100.

Referring to FIG. 3E, a plurality of openings 308 may also be formed in the passivation layer 302 to expose the underlying silicon substrate 100. The underlying silicon-substrate 100 may be selectively doped adjacent to each opening 308 to form a respective doped region 310 having a conductivity opposite to that of the doped regions 306. For example, each doped region 306 may be n-type doped and each doped region 310 may be p-type doped or vice versa. Thus, a p-n semiconductor structure is formed by the alternating doped regions 306 and 310.

Referring to FIG. 3F, metallic material may be plated within each opening 304 and 308 to form electrical contacts 312a and 312b. The electrical contacts 312a are in electrical contact with respective doped regions 306 and the electrical contacts 312b are in electrical contact with the respective doped regions 310. The electrical contacts 312a and 312b may be plated using any of the previously described plating processes (e.g., electroless plating or electroplating) and materials used for the buried electrical contacts 128 shown in FIG. 11.

Referring to the plan view of FIG. 3G, a dielectric layer 314 (e.g., a silicon dioxide, silicon nitride, or other suitable dielectric material) may be formed over the passivation layer 302 and each electrical contact 312a and 312b formed therein. Respective vias (not shown) may be formed to extend through the thickness of the dielectric layer 314 and positioned over corresponding ends of each electrical contact 312a and 312b. Additionally, first and second bus-bar grooves (not shown) may be formed in the dielectric layer 314 that extend transversely relative to the electrical contacts 312a and 312b. Such vias and grooves may be formed using photolithographic techniques or other suitable methods. Metallic material may be plated within the bus-bar groove and vias associated with the electrical contacts 312a to form bus bar 316a that is electrically connected to the electrical contacts 312a through metallic material plated into associated vias. Metallic material may also be plated within the bus-bar groove and vias associated with the electrical contacts 312b to form bus bar 316b that is electrically connected to electrical contacts 312b through metallic material plated into associated vias. The bus bars 316a and 316b may be plated into the bus-bar grooves using the same materials and plating techniques as the electrical contacts 312a and 312b.

Solder-wettable layers (not shown) may also be plated onto the bus bars 316a and 316b to improve solderability, if desired, using any of the aforementioned plating techniques. For example, when the bus bars 316a and 316b are made from nickel or a nickel alloy, the solder-wettable layer may comprise copper, tin, a noble metal, or alloys of any of the preceding metals that is electrolessly or electroplated onto the respective exposed surfaces of the bus bars 316a and 316b.

During use, the front surface 102 of the solar-cell structure is irradiated with solar radiation that generates electron-hole pairs proximate to the front surface 102. However, unlike the solar-cell structure shown in FIG. 1K, incident solar radiation is not obstructed because the electrical contacts 312a and 312b and bus bars 316a and 316b are formed over the back surface 104 of the silicon substrate 100 as opposed to the front surface 102. The photo-generated holes may diffuse to the p-type doped regions (e.g., doped region 310) and the photo-generated electrons may diffuse to the n-type doped regions (e.g., doped region 306) so that current may be transmitted to power an external circuit via the bus bar 316a and 316b.

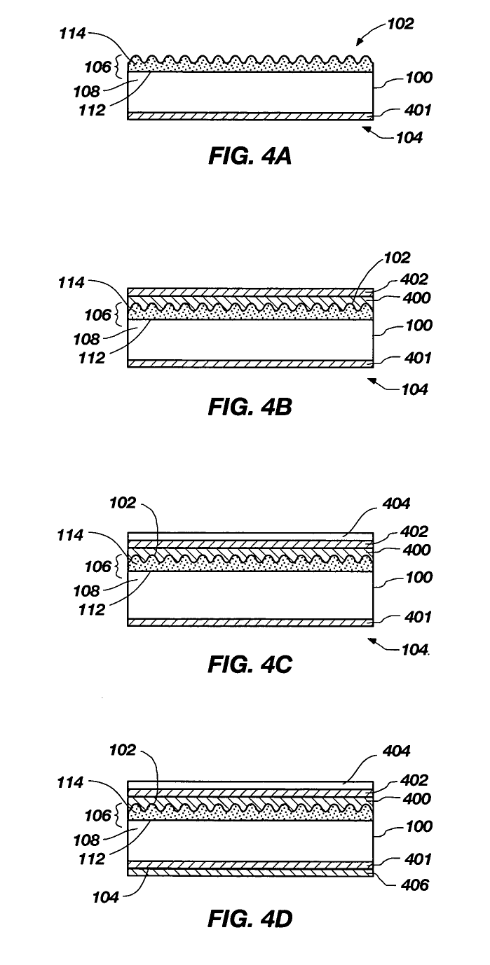

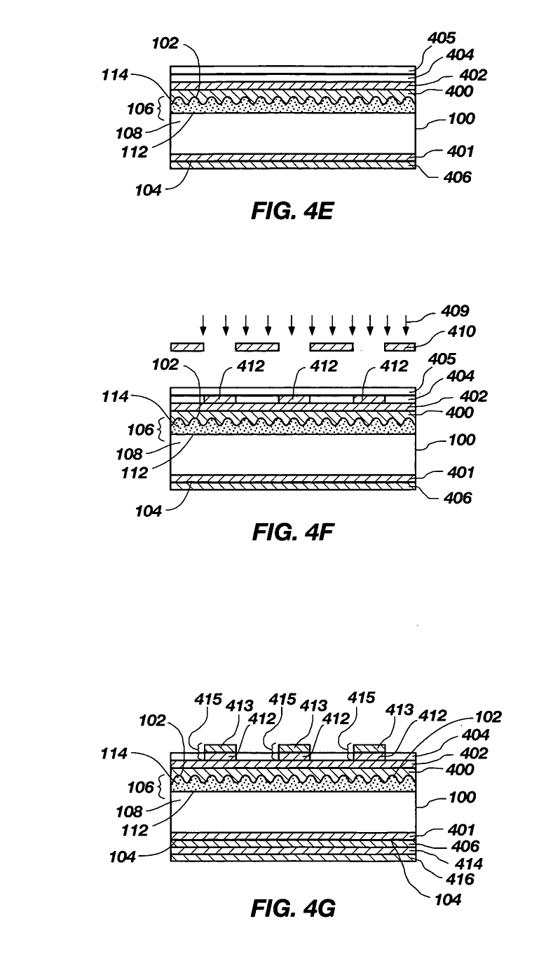

FIGS. 4A-4G are cross-sectional views illustrating various stages in a method of fabricating a solar-cell structure by selectively plating electrical contacts onto electrical contact regions formed in a photo-catalytic layer according to another embodiment of the invention. Referring to FIG. 4A, the structure shown in FIG. 1D may be provided. In the illustrated embodiment, an additional porous-silicon layer 401 that extends inwardly from the back surface 104 is also electrochemically formed using the same techniques as for the porous-silicon layer 114. However, in other embodiments, the porous-silicon layer 401 may be omitted. Referring to FIG. 4B, an ARC 400 may be deposited over the textured front surface 102 of the silicon substrate 100. For example, the ARC 400 may comprise zinc oxide (“ZnO”) deposited (e.g., via CVD, sputtering, or another suitable deposition technique), which is electrically conductive and substantially transparent to the dominant wavelengths of the solar radiation spectrum. An indium tin oxide (“ITO”) layer 402 may also be deposited on the ARC 400 using sputtering or evaporation. The ITO layer 402 is also electrically conductive and substantially transparent to the dominant wavelengths of the solar radiation spectrum.

Referring to FIG. 4C, a photo-catalytic layer 404 (e.g., amorphous titanium dioxide having palladium ions) may be applied to the ITO layer 402. For example, the photo-catalytic layer 404 may be applied via spin coating using a palladium ion and titanium ion containing solution.

Referring to FIG. 4D, a metallization layer 406 may be formed on the back surface 104 of the silicon substrate 100. For example, the metallization layer 406 may comprise an aluminum-copper alloy deposited via sputtering, evaporation, CVD, or ALD.

Referring to FIG. 4E, a layer of polyvinyl alcohol (“PVA”) 405 or other hole scavenger may be applied to the photo-catalytic layer 404. Referring to FIG. 4F, selective regions of the photo-catalytic layer 404 may be exposed to electromagnetic radiation 409 through a patterned mask 410. A plurality of electrical contact regions 412 (e.g., elongated fingers electrically interconnected via a bus bar (not shown)) may be selectively formed within the photo-catalytic layer 404 in regions corresponding to the regions of the patterned mask 410 through which electromagnetic radiation 409 can pass therethrough. For example, when the photo-catalytic layer 404 comprises amorphous titanium oxide having palladium ions therein, the PVA layer 405 functions as a hole scavenger so that the palladium ions may be reduced to form palladium regions (i.e., the electrical contact regions 412) responsive to exposure to the electromagnetic radiation 409 through the patterned mask 410.

Referring to FIG. 4G, after forming the electrical contact regions 412, the layer of PVA layer 405 may be removed. Then, copper, nickel, silver, cobalt, or alloys of any of the preceding metals may be electrolessly or electroplated on the electrical contact regions 412 to form a layer 413. Each layer 413 forms the bulk of a larger electrical contact 415 formed of respective electrical contact regions 412 and layers 413. A nickel-containing layer 414 (e.g., nickel or nickel alloy) may also be plated on the metallization layer 406 via an electroless or electroplating process. In some embodiments, the nickel-containing layer 414 may be plated concurrently with the layers 413. For example, when the metallization layer 406 comprises an aluminum-copper alloy, the nickel-containing layer 414 may be electrolessly plated without having to pre-treat the metallization layer 414. A solder-wettable layer 416 may be plated on the nickel-containing layer 414, such as a noble metal- (e.g., silver), a tin-, or a copper-containing layer that is electrolessly plated or plated via contact displacement deposition.

In other embodiments of the invention, the electrical contact regions 412 may be selectively formed within the photo-catalytic layer 404 prior to deposition of the metallization layer 406.

The solar-cell structure illustrated in FIG. 4G functions the same or similar as the solar-cell structure illustrated in FIG. 1K. Therefore, in the interest of brevity, a description of the functioning of the solar-cell structure so-formed is not provided herein.

It is noted that in other embodiments of the invention, the porous-silicon layers 114 and 401 may be employed as a gettering layer and removed via etching after gettering. In such an embodiment, after removal of the porous-silicon layers 114 and 401 having gettered impurities therein, the ARC 400 may be deposited onto the etched surface of the remaining n-region 110 (not shown). Further, in other embodiments of the invention, the buried p-n junction 112 may be formed by doping after gettering in a porous-silicon layer and removal thereof.

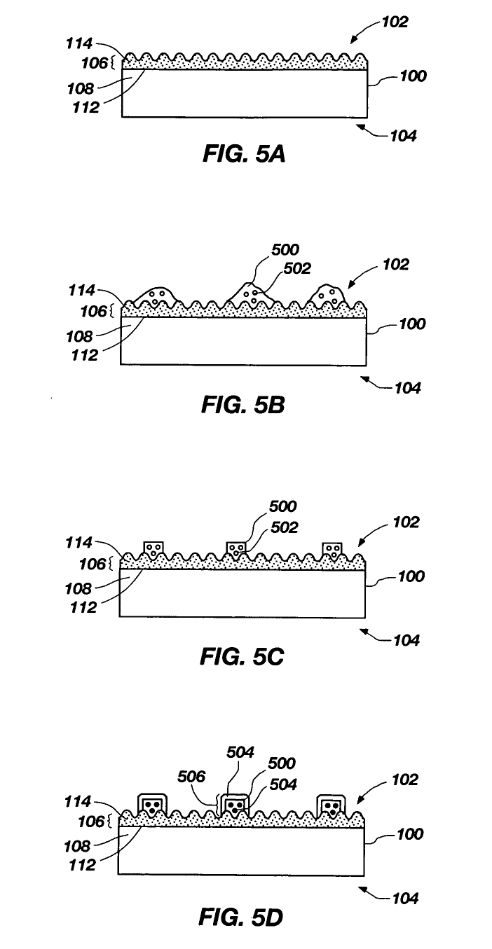

FIGS. 5A-5D are different cross-sectional views illustrating various stages in a method of fabricating a solar-cell structure having a plurality of electrical contacts including a screen-printed portion and a plated portion according to another embodiment of the invention. Referring to FIG. 5A, the in-process structure shown in FIG. 1D may be provided.

Referring to FIG. 5B, a plurality of precursor electrical contacts 500 may be applied to the front surface 102 of the porous-silicon layer 114. For example, each precursor electrical contact 500 may comprise screen printed silver contacts configured as conductive lines electrically interconnected via a bus bar. As illustrated, each precursor electrical contact 500 may include pores 502 formed as a result of the screen printing process. It is noted that in other embodiments of the invention, when the porous-silicon layer 114 is employed as a gettering layer, the precursor electrical contacts 500 may be formed on the remaining n-region 110 after removal of the gettering layer containing gettered impurities therein. In yet a further embodiment of the invention, the buried p-n junction 112 may be formed after gettering in a porous-silicon layer and removal thereof.

Referring to FIG. 5C, the precursor electrical contacts 500 may be etched to shape the precursor electrical contacts 500 so that they exhibit a more well-defined generally rectangular cross-sectional geometry. Furthermore, the etching process also reduces a cross-sectional area of each precursor electrical contact 500. For example, the width of respective precursor electrical contacts 500 may be reduced from about 50 μm-150 μm to about 1 μm-90 μm (e.g., about 1 μm-90 μm). As an example, dilute nitric acid (e.g., about 5 percent by volume) may be used to etch screen printed silver contacts. The in-process structure shown in FIG. 5C may be fired at a sufficient temperature to densify and promote electrical contact of the precursor electrical contacts 500 with the underlying porous-silicon layer 114.

Referring to FIG. 5D, the etched precursor electrical contacts 500 may be selectively plated with a plated portion 504 to cover the precursor electrical contact 500, and further at least partially fill the pores 502 to form electrical contacts 506. For example, the plated portion 504 may be electrolessly plated copper. By coating the precursor electrical contacts 500 with the plated portion 504 and partially or completely filling the pores 502, the electrical resistivity of the electrical contacts 506 may be lower than the precursor electrical contacts 500 without the plated portions 504. Furthermore, etching the precursor electrical contact 500 reduces the lateral dimensions of each precursor electrical contact 500 so that the previously described shadowing effect therefrom is reduced and, thus, improves operational efficiency.

As previously described, the exposed portions of the porous-silicon layer 114 between adjacent electrical contacts 500 may be passivated and a rear metallization layer may be provided, and in the interest of brevity is not discussed in detail. For example, a rear passivation layer and metallization layer may be provided in the same or similar manner described with respect to FIGS. 1A-1K. Furthermore, the operation of such a solar-cell structure is similar to the operation of the solar-cell structure shown in FIG. 1K.

From the foregoing it will be appreciated that, although specific embodiments of the invention have been described herein for purposes of illustration, various modifications may be made without deviating from the spirit and scope of the invention.

1. A method of fabricating a solar-cell structure, comprising:
providing a substrate including a front surface and an opposing back surface;
electrochemically forming a porous-silicon layer from a portion of the substrate that extends inwardly from the front surface;
electrochemically passivating a portion of the porous-silicon layer; and
plating metallic material to form at least a portion of each of a plurality of electrical contacts that are electrically coupled the substrate.

2. The method of claim 1 wherein electrochemically forming a porous-silicon layer from a portion of the substrate that extends inwardly from the front surface comprises:
anodically etching the portion of the substrate.

3. The method of claim 2 wherein anodically etching the portion of the substrate comprises:
anodically etching the portion of the substrate in hydrofluoric acid.

4. The method of claim 1 wherein electrochemically passivating a portion of the porous-silicon layer comprises:
anodically oxidizing the portion of the porous-silicon layer in an acidic solution or basic solution to form a silicon dioxide layer.

5. The method of claim 1 wherein electrochemically forming porous-silicon layer from a portion of a substrate comprises:
forming the porous-silicon layer from a portion of a doped region, wherein the doped region extends inwardly from the front surface of the substrate to form a p-n junction.

6. The method of claim 1, further comprising:
doping at least the porous-silicon layer to form a p-n junction.

7. The method of claim 1:
further comprising forming a plurality of grooves each of which extends inwardly from at least the front surface; and
wherein plating metallic material to form at least a portion of each of a plurality of electrical contacts that are electrically coupled the substrate comprises plating the metallic material into each of the grooves.

8. The method of claim 7 wherein forming a plurality of grooves each of which extends inwardly from at least the front surface comprises:
laser ablating or etching the plurality of grooves in the substrate.

9. The method of claim 7, further comprising:
forming a metallization layer over the back surface of the substrate.

10. The method of claim 1:
further comprising forming a plurality of grooves each of which extends inwardly from at least the front surface;
further comprising plating a nickel-containing layer into each of the grooves;
further comprising forming a metallization layer over the back surface of the substrate, wherein the metallization layer comprises an aluminum-copper alloy; and
further comprising electrolessly plating a nickel-containing layer on the metallization layer substantially simultaneously with the act of electrolessly plating a nickel-containing layer into each of the grooves; and
wherein plating metallic material to form at least a portion of each of a plurality of electrical contacts that are electrically coupled the substrate comprises electrolessly plating conductive material onto the nickel-containing material in each of the grooves.

11. The method of claim 1:
further comprising forming a plurality of grooves so that each of the grooves extends inwardly from at least the front surface prior to the act of electrochemically forming a porous-silicon layer from a portion of the substrate so that the porous-silicon layer defines each of the grooves;
wherein plating metallic material to form at least a portion of each of a plurality of electrical contacts that are electrically coupled the substrate comprises plating the metallic material onto the porous-silicon layer that defines each of the grooves.

12. The method of claim 1 wherein plating metallic material to form at least a portion of each of a plurality of electrical contacts that are electrically coupled the substrate comprises:
electroplating the metallic material.

13. The method of claim 1 wherein plating metallic material to form at least a portion of each of a plurality of electrical contacts that are electrically coupled the substrate comprises:
electrolessly plating the metallic material.

14. The method of claim 1 wherein the metallic material is selected from the group consisting of copper, nickel, silver, gold, palladium, and alloys thereof.

15. The method of claim 1, further comprising:
forming a plurality of grooves each of which extends inwardly through the front surface or through an electrochemically-formed passivation layer formed on the back surface.

16. The method of claim 15:
wherein the metallic material comprises an alloy including at least one barrier-forming constituent; and
wherein plating metallic material to form at least a portion of each of a plurality of electrical contacts that are electrically coupled the substrate comprises plating the metallic material within each of the grooves; and
further comprising segregating the at least one barrier constituent to respective surfaces of the substrate that define each of the grooves.

17. The method of claim 16 wherein the at least one barrier-forming constituent comprises at least one refractory metal.

18. The method of claim 16 wherein segregating the at least one barrier constituent to respective surfaces that define each of the grooves comprises:
annealing the metallic material at a temperature below about 400° C.

19. The method of claim 15 wherein forming a plurality of grooves each of which extends inwardly through the front surface or through an electrochemically-formed passivation layer formed on the back surface comprises:
laser ablating or etching the plurality of grooves in the substrate.

20. The method of claim 1, further comprising:
texturing the front surface of the substrate.

21. The method of claim 20 wherein texturing the front surface of the substrate comprises:
anisotropically etching the front surface.

22. The method of claim 1, further comprising:
electrochemically passivating the back surface of the substrate.

23. The method of claim 1:
further comprising forming a plurality of doped regions located at least proximate to the back surface; and
wherein plating metallic material to form at least a portion of each of a plurality of electrical contacts that are electrically coupled the substrate comprises plating the electrical contacts so that each electrically contacts a corresponding one of the doped regions.

24. The method of claim 1:
further comprising applying a photo-catalytic layer over the porous-silicon layer prior to plating the metallic material;
further comprising selectively forming electrical contact regions within the photo-catalytic layer; and
wherein plating metallic material to form at least a portion of each of a plurality of electrical contacts that are electrically coupled the substrate comprises electrolessly plating the metallic material onto the electrical contact regions.

25. The method of claim 24, further comprising:
forming at least one electrically conductive, substantially transparent layer between the porous-silicon layer and the photo-catalytic layer.

26. The method of claim 25 wherein the at least one electrically conductive, substantially transparent layer comprises zinc oxide.

27. The method of claim 25 wherein the at least one electrically conductive, substantially transparent layer comprises indium tin oxide.

28. The method of claim 24 wherein selectively forming electrical contact regions within the photo-catalytic layer comprises:
selectively exposing the photo-catalytic layer to electromagnetic radiation to form the electrical contact regions.

29. The method of claim 24 wherein the photo-catalytic layer comprises amorphous titanium oxide having palladium ions therein.

30. The method of claim 24, further comprising:
forming a metallization layer in electrical contact with the substrate and over the back surface of the substrate.

31. The method of claim 1:
further comprising, prior to the act of plating metallic material:
screen printing precursor electrical contacts to be electrically coupled to the substrate; and
etching the precursor electrical contacts; and
wherein plating metallic material to form at least a portion of each of a plurality of electrical contacts that are electrically coupled the substrate comprises plating the metallic material to coat and at least partially fill voids present in the etched precursor electrical contacts.

32. The method of claim 1 wherein the substrate comprises a polycrystalline-silicon substrate.

33. The method of claim 1 wherein the substrate comprises a single-crystal silicon substrate.

34. The method of claim 1 wherein the substrate exhibits an n-type or p-type conductivity.

35. A solar-cell structure, comprising:
a substrate having a front surface and an opposing back surface, the substrate comprising:
a semiconductor structure including at least one p-region and at least one n-region;
a porous-silicon layer formed in a portion of the substrate; and
a passivation layer formed from a portion of the porous-silicon layer and extending inwardly from the front surface; and
a plurality of electrical contacts electrically coupled to the semiconductor structure, at least a portion of each of the electrical contacts including a plated portion.

36. The solar-cell structure of claim 35 wherein each of the electrical contacts extends inwardly from at least the front surface of the substrate.

37. The solar-cell structure of claim 36 wherein each of the electrical contacts comprises an electroplated, buried electrical contact.

38. The solar-cell structure of claim 36 wherein each of the electrical contacts comprises an electrolessly plated, buried electrical contact.

39. The solar-cell structure of claim 36 wherein:
the substrate comprises a plurality of grooves formed therein that extend inwardly from at least the front surface, and a portion of the porous-silicon layer defines each of the grooves; and
each of the electrical contacts fills a corresponding one of the grooves to establish electrical contact with the semiconductor structure.

40. The solar-cell structure of claim 36 wherein:
the substrate comprises a rear passivation layer formed on the back surface, a plurality of openings formed through the rear passivation layer, and a plurality of doped regions each of which is formed adjacent to a corresponding one of the openings; and
each of the electrical contacts fills a corresponding one of the openings to establish electrical contact with substrate.

41. The solar-cell structure of claim 36 wherein the rear passivation layer comprises silicon dioxide having a composition characteristic of being formed by an anodic oxidation process.

42. The solar-cell structure of claim 35 wherein each of the contacts comprises a barrier layer formed at an interface with the substrate.

43. The solar-cell structure of claim 42 wherein the barrier layer comprises at least one refractory metal.

44. The solar-cell structure of claim 35 wherein each of the electrical contacts comprises a metallic material selected from the group consisting of copper, nickel, silver, gold, palladium, and alloys thereof.

45. The solar-cell structure of claim 35 wherein the porous-silicon layer has an energy band gap that is greater than an energy band gap of the semiconductor structure.

46. The solar-cell structure of claim 35, further comprising:
a photo-catalytic layer formed over the front surface of the substrate, the photo-catalytic layer having electrical contact regions formed therein, each of the plated portions being electrolessly plated on a corresponding one of the electrical contact regions.

47. The solar-cell structure of claim 46 wherein the photo-catalytic layer comprises titanium dioxide.

48. The solar-cell structure of claim 46, further comprising:
one or more electrically conductive, substantially transparent layers formed between the front surface and the photo-catalytic layer.

49. The solar-cell structure of claim 48 wherein the one or more electrically conductive, substantially transparent layers comprises one or more of the following materials: indium tin oxide and zinc oxide.

50. The solar-cell structure of claim 35 wherein each of the electrical contacts comprises screen-printed portion having pores therein and a plated portion that at least partially fills the pores with plated metallic material.

51. The solar-cell structure of claim 35 wherein the semiconductor structure comprises a p-n junction located proximate to the front surface that is formed between the at least one p-region and the at least one n-region.

52. The solar-cell structure of claim 35 wherein the at least one p-region and the at least one n-region of the semiconductor structure comprises alternating p-doped and n-doped regions formed at least proximate to the back surface of the substrate.

53. The solar-cell structure of claim 35 wherein the substrate comprises a polycrystalline-silicon substrate.

54. The solar-cell structure of claim 35 wherein the substrate comprise a single-crystal silicon substrate.

55. A method of fabricating a solar-cell structure, comprising:
providing a substrate including a front surface and an opposing back surface;
electrochemically forming a porous-silicon layer from a portion of the substrate;
gettering at least a portion of impurities present in the substrate in the porous-silicon layer;
removing the porous-silicon layer having impurities gettered therein; and
after removing the porous-silicon layer, electrochemically passivating an exposed portion of the substrate; and
plating metallic material to form at least a portion of each of a plurality of electrical contacts that are electrically coupled to the substrate.

56. The method of claim 55 wherein gettering at least a portion of impurities present in the substrate in the porous-silicon layer comprises:
annealing the substrate with the porous-silicon layer.

57. The method of claim 55 wherein removing the porous-silicon layer having impurities gettered therein comprises:
etching the porous-silicon layer having impurities gettered therein.
